(19) United States
(12) Patent Application Publication
(10) Pub. No.: US 2026/0118452 A1
(43) Pub. Date: Apr. 30, 2026

(54) HYPERPOLARIZERS WITH A LOAD-LOCK CHAMBER FOR ALKALI METAL

(71) Applicant: Polarean, Inc., Durham, NC (US)

(72) Inventor: Andrew K. Dummer, Chapel Hill, NC (US)

(21) Appl. No.: 19/003,184

(22) Filed: Dec. 27, 2024

Related U.S. Application Data
(60) Provisional application No. 63/619,350, filed on Jan. 10, 2024.

(51) Int. Cl. G01R 33/26

(52) U.S. Cl. CPC G01R 33/26

(57) ABSTRACT

Hyperpolarizers are provided with a load lock chamber positioned upstream of the optical pumping cell. The load-lock chamber is configured to open and to sealably close to allow a user to load an alkali metal source therein. The alkali metal is vaporized and fluidly introduced to the optical pumping cell during SEOP. The load lock chamber has a heater that heats the alkali metal source to vaporize the alkali metal held in the load lock chamber. The alkali metal can be provided in a sealed canister that is opened onsite and loaded into the load lock chamber for use in the hyperpolarizer. The alkali metal in the sealed canister can be or include one or more tablets comprising Rb in a solid form and in a relatively small amount such as in a range of 0.5 g-5 g.

### RELATED APPLICATIONS

This patent application claims priority to and the benefit of U.S. Provisional Patent Application Ser. No. 63/619,350, filed Jan. 10, 2024, the contents of which are hereby incorporated by reference as if recited in full herein.

### FIELD OF THE INVENTION

The present invention relates to the hyperpolarized noble gas systems (hyperpolarizers) for providing hyperpolarized noble gas for use in magnetic resonance imaging (“MRI”) applications.

### BACKGROUND

Conventionally, MRI has been used to produce images by exciting the nuclei of hydrogen atoms (present in water molecules) in the human body. MRI imaging with polarized noble gases can produce improved images of certain areas and regions of the body. Polarized Helium-3 (“³He”) and Xenon-129 (“¹²⁹Xe”) have been found to be particularly suited for this purpose.

Hyperpolarizers are used to produce and accumulate polarized noble gases. Hyperpolarizers artificially enhance the polarization of certain noble gas nuclei (such as ¹²⁹Xe or ³He) over the natural or equilibrium levels, i.e., the Boltzmann polarization. Such an increase is desirable because it enhances and increases the Magnetic Resonance Imaging (“MRI”) signal intensity, allowing physicians to obtain better images of the substance in the body. See U.S. Pat. No. 5,642,625 to Cates et al. and U.S. Pat. No. 5,545,396 to Albert et al., the contents of which are hereby incorporated herein by reference as if recited in full herein.

In order to produce the hyperpolarized gas, the noble gas is typically blended with optically pumped alkali metal vapors such as rubidium (“Rb”). These optically pumped metal vapors collide with the nuclei of the noble gas and hyperpolarize the noble gas through a phenomenon known as “spin-exchange.” The “optical pumping” of the alkali metal vapor is produced by irradiating the alkali-metal vapor with circularly polarized light at the wavelength of the first principal resonance for the alkali metal (e.g., 795 nm for Rb). Generally stated, the ground state atoms become excited, then subsequently decay back to the ground state. Under a modest magnetic field (typically about 10 Gauss), the cycling of atoms between the ground and excited states can yield nearly 100% polarization of the atoms in a few microseconds. This polarization is generally carried by the lone valence electron characteristics of the alkali metal. In the presence of non-zero nuclear spin noble gases, the alkali-metal vapor atoms can collide with the noble gas atoms in a manner in which the polarization of the valence electrons is transferred to the noble-gas nuclei through a mutual spin flip “spin-exchange.”

Conventionally, lasers have been used to optically pump the alkali metals. Various lasers emit light signals over various wavelength bands. In order to improve the optical pumping process for certain types of lasers (particularly those with broader bandwidth emissions), the absorption or resonance line width of the alkali metal, typically comprising alkali metal such as Rubidium (“Rb”) can be made broader to more closely correspond with the particular laser emission bandwidth of the selected laser. This broadening can be achieved by pressure broadening, i.e., by using a buffer gas in the optical pumping chamber. Collisions of the alkali metal vapor with a buffer gas will lead to a broadening of the alkali's absorption bandwidth.

In traditional spin exchange optical pumping (SEOP) constant flow systems, a helium-nitrogen-(¹²⁹) xenon gas mixture flows through the optical cell where the SEOP process occurs. Subsequently, the hyperpolarized ¹²⁹Xe can be frozen, separated and collected from other gases in this gas mixture. Following the collection, the frozen ¹²⁹Xe is rapidly warmed back to a gaseous state which is flowably collected in a collection container, such as a TEDLAR bag for administration to patients. For examples of cryogenic collection systems, see, e.g., U.S. Pat. Nos. 5,809,801; 6,305,190 and 6,735,977, and co-pending U.S. Provisional Patent Application Ser. Nos. 63/484,044 and 63/484,078, filed Feb. 9, 2023, the contents of which are hereby incorporated by reference as if recited in full herein.

The alkali metal, e.g., Rb, for the optical pumping cell is typically pre-loaded into the optical pumping cell or a pre-saturation chamber forming a cooperating component thereof and shipped to a use site. See, e.g., U.S. Pat. No. 11,052,161, the contents of which are hereby incorporated by reference as if recited in full herein. However, there is a need for systems that can allow the Rb to be loaded and reloaded into the hyperpolarizer at a clinical site to facilitate clinical use and/or allow optical pumping cells and/or pre-saturation chambers to be shipped to client sites free of alkali metal such as Rb.

### SUMMARY

Embodiments of the present invention provide hyperpolarizers with a load-lock chamber configured to allow a user to load and reload an alkali metal source into the load-lock chamber onsite at a hyperpolarized gas production site.

Embodiments of the present invention are directed to a hyperpolarizer that includes: a spin exchange optical pumping cell; and a load-lock chamber positioned upstream of and in fluid communication with the spin exchange optical pumping cell. The load-lock chamber is configured to hold an alkali metal source therein for vaporization of alkali metal from the alkali metal source into a gas stream provided to the spin exchange optical pumping cell.

The load-lock chamber can be configured to have an open position and a sealably closed position. When in the sealably closed position, the alkali metal source is heated and vaporized alkali metal is provided to the gas stream.

The hyperpolarizer can further include a container holding the alkali metal source in a solid state in the load-lock chamber and a basket heater in the load-lock chamber at least partially surrounding the container.

A body or bodies providing the load-lock chamber, the container and the basket heater are all formed of non-ferromagnetic materials.

The load-lock chamber can have a first end portion that is in fluid communication with and that merges into an alkali metal vapor mixing chamber, both of which reside upstream of the spin exchange optical pumping cell.

The load-lock chamber can have a second end portion that can have a first member that is sealably and releasably coupled to a second member and the second member can have a closed primary surface and can include at least one electrical feed through extending through the closed primary surface and can be configured to couple to a power source.

The first end portion can be borosilicate glass. The first member can have or be a non-ferromagnetic cylinder with a flange sealed to the borosilicate glass. The second member can have a non-ferromagnetic disk with a flange that faces and abuts the flange of the first member when the load-lock chamber is in a closed position.

The hyperpolarizer can have a first conductive post and a second conductive post extending in the load-lock chamber, each of which can terminate adjacent the pre-saturation vapor mixing chamber. The basket heater can be attached to the first conductive post and the second conductive post.

The hyperpolarizer can include an alkali metal source held by a container in the load-lock chamber. The alkali metal source can be provided in a solid state.

The alkali metal source can include at least one of Rb, Cs, Na, and K.

The alkali metal source can include Rubidium.

The alkali metal source can be provided as one or a plurality of Rb/Amax tablets.

A sealed canister can provide the alkali metal source. The sealed canister can be configured to be opened at a use site to provide the alkali metal source for the load-lock chamber.

The hyperpolarizer can include a pressurized gas manifold in fluid communication with the load-lock chamber and a supply of ultra-high purity nitrogen coupled to the pressurized gas manifold. The hyperpolarizer can be configured to direct ultra-high purity nitrogen to flow through the pressurized gas manifold and out the load-lock chamber when the load-lock chamber is in an open state for reloading alkali metal source into the load-lock chamber to thereby inhibit impurities from entering the load-lock chamber.

Yet other embodiments of the present invention provide a flow-through spin exchange optical pumping (SEOP) hyperpolarized gas production system for producing hyperpolarized gas. The SEOP hyperpolarized gas production system includes: a pressurized noble gas mixture in a gas manifold; a load-lock chamber in fluid communication with the gas manifold with the pressurized noble gas mixture and configured to provide vaporized alkali metal to the pressurized noble gas mixture; and a flow-through optical pumping cell in fluid communication with the gas manifold with the pressurized gas mixture and positioned downstream of the load-lock chamber. The flow-through optical pumping cell is configured to provide hyperpolarized noble gas.

The hyperpolarized noble gas can be hyperpolarized ¹²⁹Xe gas.

The flow-through SEOP gas production system can further include an alkali metal mixing chamber in fluid communication with the load-lock chamber and positioned upstream of the flow-through optical pumping cell. A magnetic field B0 can surround at least part of the flow-through optical pumping cell. The load lock chamber can be positioned in or adjacent the magnetic field and can be formed with only non-ferromagnetic materials.

Other aspects of the present invention are directed to methods of providing alkali metal for a hyperpolarizer. The methods include: providing a hyperpolarizer with a load-lock chamber, with the load-lock chamber positioned upstream of an optical pumping cell; opening the load-lock chamber; inserting a solid alkali metal source into a container held inside the load-lock chamber; sealably closing the load-lock chamber with the inserted alkali metal source; then vaporizing alkali metal from the alkali metal source into a noble gas mixture stream; flowably providing the noble gas mixture stream with the vaporized alkali metal to the optical pumping cell; and producing at least one batch of hyperpolarized noble gas.

The method can further include: opening the load-lock chamber; then inserting an additional solid alkali metal source into the container; and (sealably) closing the load-lock chamber with the additionally inserted solid alkali metal source and repeating the vaporizing, flowably providing and producing actions.

The method can include providing a sealed canister of the alkali metal source with the alkali metal source configured as a plurality or tablets that include Rb (for vaporization).

The load-lock chamber can be coupled to a pressurized fluid flow manifold of the hyperpolarizer and can remain coupled to the fluid flow manifold during the opening actions with ultra-high purity nitrogen directed to flow from the pressurized fluid flow manifold and out of the opened load-lock chamber.

The at least one batch of hyperpolarized noble gas can be at least one bolus amount of inhalable hyperpolarized ¹²⁹Xe gas.

As will be appreciated by those of skill in the art in light of the above discussion, the present invention may be embodied as methods, systems and/or computer program products or combinations of same. In addition, it is noted that aspects of the invention described with respect to one embodiment, may be incorporated in a different embodiment although not specifically described relative thereto. That is, all embodiments and/or features of any embodiment can be combined in any way and/or combination for any number of desired activities and/or any degree of activity performance complexity or variability. Applicant reserves the right to change any originally filed claim or file any new claim accordingly, including the right to be able to amend any originally filed claim to depend from and/or incorporate any feature of any other claim although not originally claimed in that manner. These and other objects and/or aspects of the present invention are explained in detail in the specification set forth below.

The foregoing and other objects and aspects of the present invention are explained in detail herein.

### BRIEF DESCRIPTION OF THE DRAWINGS

Other features of the present invention will be more readily understood from the following detailed description of exemplary embodiments thereof when read in conjunction with the accompanying drawings.

FIG. 1 is a schematic illustration of a hyperpolarizer with a load-lock chamber according to embodiments of the present invention.

FIG. 2 is a front view of a portion of a hyperpolarizer with a load-lock chamber according to embodiments of the present invention.

FIG. 3 is an enlarged view of a portion of the load-lock chamber shown in FIG. 2.

FIG. 4 is a side perspective view of a portion of a hyperpolarizer with the load-lock chamber shown in FIG. 2.

FIG. 5 is a side perspective view of another embodiment of a portion of a hyperpolarizer with a load-lock chamber according to embodiments of the present invention.

FIG. 6 is an enlarged view of an example sealed container comprising alkali metal according to embodiments of the present invention.

FIG. 7A is partially disassembled view of the load-lock chamber shown in FIG. 2.

FIG. 7B is a partially exploded front view of the load-lock chamber shown in FIG. 7A.

FIG. 7C is an enlarged view of components of the load-lock chamber shown in FIG. 7A.

FIG. 8 is an end view of a portion of the load-lock chamber shown in FIG. 7A.

FIG. 9 is a side assembled view of the load-lock chamber shown in FIG. 7A.

FIG. 10 is a greatly enlarged side view of a basket heater and crucible of the load-lock chamber shown in FIG. 7A according to embodiments of the present invention.

FIG. 11 is a disassembled view of the basket heater and cooperating crucible shown in FIG. 10.

FIG. 12 is a schematic illustration of alkali metal pellets for the crucible of a load-lock chamber according to embodiments of the present invention.

FIG. 13 is a flow chart of example actions for providing alkali metal for a hyperpolarizer according to embodiments of the present invention.

### DETAILED DESCRIPTION

The present invention will now be described more fully hereinafter with reference to the accompanying figures, in which preferred embodiments of the invention are shown. This invention may, however, be embodied in many different forms and should not be construed as limited to the embodiments set forth herein.

Like numbers refer to like elements throughout. In the figures, layers, regions and/or components may be exaggerated for clarity. The word “Figure” is used interchangeably with the abbreviated forms “FIG.” and “Fig.” in the text and/or drawings. Broken lines illustrate optional features or operations unless specified otherwise. In the description of the present invention that follows, certain terms are employed to refer to the positional relationship of certain structures relative to other structures.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

It will also be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention. The sequence of operations (or steps) is not limited to the order presented in the claims or figures unless specifically indicated otherwise.

Spatially relative terms, such as “under”, “below”, “lower”, “over”, “upper” and the like, may be used herein for case of description to describe one element or feature's relationship to another element(s) or feature(s) as illustrated in the figures. It will be understood that the spatially relative terms are intended to encompass different orientations of the data or information in use or operation in addition to the orientation depicted in the figures. For example, if data in a window view of the system in the figures is inverted, elements described as “under” or “beneath” other elements or features would then be oriented “over” the other elements or features. Thus, the exemplary term “under” can encompass both an orientation of over and under. The display view may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

As used herein, the term “forward” and derivatives thereof refer to the general direction a noble gas mixture travels as it moves through the hyperpolarizer system; this term is meant to be synonymous with the term “downstream” which is often used in manufacturing environments to indicate that certain material being acted upon is farther along in the manufacturing process than other material. Conversely, the terms “rearward” and “upstream” and derivatives thereof refer to the directions opposite, respectively, the forward and downstream directions.

Also, as described herein, target gases such as polarized gases can be collected, frozen, then thawed, and used. Polarized/hyperpolarized noble gases can be used in MRI applications. For ease of description, the term “frozen gas” means that the gas has been frozen into a solid state. The term “liquid gas” means that the frozen gas has been or is being liquefied into a liquid state. The term “gas” alone refers to the gaseous state. Thus, although each term includes the word “gas”, this word, used with a state modifier is used to name and descriptively track the gas which is produced. For hyperpolarized/polarized gas, it is produced via a hyperpolarizer to obtain a polarized/hyperpolarized “gas” product. Therefore, as used herein, the term gas has been used in certain places to descriptively indicate a hyperpolarized noble gas product and may be used with modifiers such as solid, frozen, and liquid to describe the state or phase of that product. Although the below description is primarily described with respect to a hyperpolarized noble gas, such as ¹²⁹Xe, the devices can be used to collect other gases that freeze at 77 deg. K or above, particularly in successive relatively small quantities, such as under about 2 liters.

In some embodiments, the polarized ¹²⁹Xe gas can be produced and formulated to be suitable for internal pharmaceutical human or animal medical purposes.

The term “about” means within plus or minus 10% of a recited number.

The term “polarization friendly” means that the device is configured and formed of materials and/or chemicals that do not induce or cause more than di minimis decay (e.g., less than about 2%) of the polarization of the polarized noble gas, e.g., ¹²⁹Xe.

The term “compact” with respect to optical pumping cells, refers to optical pumping cells that are between about 50 cubic centimeters (“ccs”) to about 1000 ccs, typically between about 100 ccs and 500 ccs, in volumetric capacity.

The term “high volume” means that the polarizer is a continuous flow polarizer (or at least substantially continuous), once activated for production for a given supply of gas mixture to produce at least between about 1.5 ccs to about 500 cc's of polarized noble gas per minute, and/or between about 1000 cc's to about 10,000 cc's, or even more, per hour. The terms “polarizer” and “hyperpolarizer” are used interchangeably herein.

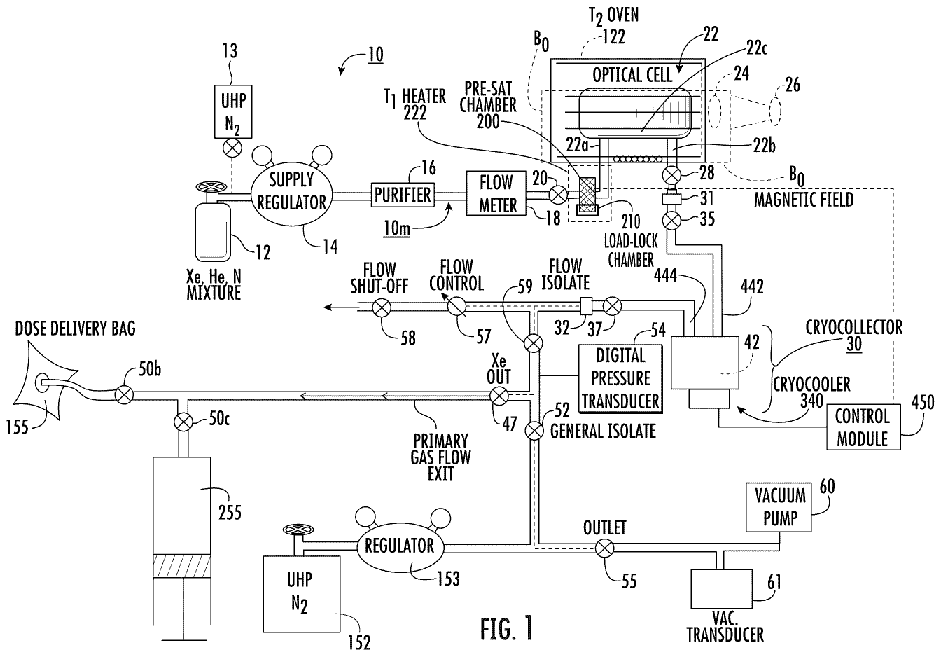

With reference to FIG. 1, an example hyperpolarizer 10 is shown. The hyperpolarizer 10 includes an optical pumping cell 22 upstream of a cryo-collection system 30 and downstream of a load-lock chamber 210. As will be discussed further below, the load-lock chamber 210 provides vaporized alkali metal to a pressurized gas mixture flowably supplied from the (incoming) fluid manifold 10m to a pre-saturation mixing chamber 200 also upstream of the optical pumping cell 22.

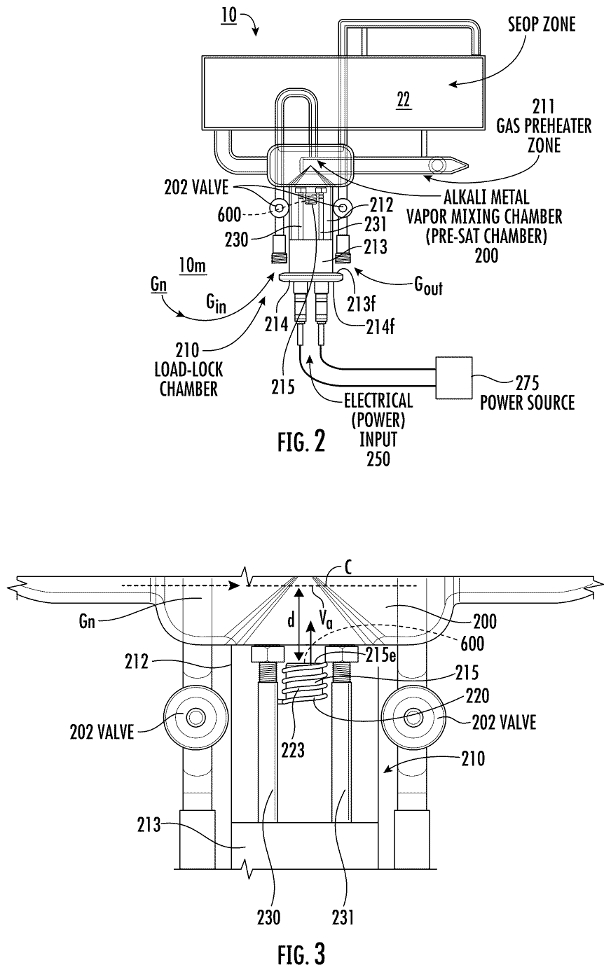

A control module 450 (FIG. 1) comprising at least one processor can be coupled to the load-lock chamber 210 for directing heat to be supplied to a container 215 (FIGS. 2, 3) holding an alkali metal source 600 (FIG. 2) therein which is vaporized into gas form and flowably introduced to an alkali metal vapor mixing chamber 200 where the vaporized alkali metal is mixed with an incoming pressurized noble gas mixture provided by manifold 10m then the pressurized noble gas mixture with the addition of the vaporized alkali metal is flowably introduced into the optical pumping cell 22 during a production cycle of the hyperpolarizer 10.

The control module 450 can be the same as or separate from the control module 450 coupled to the cryo-collection system 30 to electronically control operation thereof. It is noted that the hyperpolarizer 10 can comprise more than one cryo-collection system 30. Commercial hyperpolarizers comprising gas handling manifolds, a xenon polarizer and supporting devices are available from Polarean, Inc., Durham, North Carolina. Additional components of the hyperpolarizer 10 shown in FIG. 1 will be discussed below.

Turning now to FIG. 2, a portion of the polarizer 10 with the spin-exchange optical pumping cell 22 and the load-lock chamber 210 is shown. The load-lock chamber 210 is in fluid communication with the alkali metal vapor mixing chamber 200 and both the load-lock chamber 210 and the alkali vapor mixing chamber 200 are upstream of the optical pumping cell 22. The alkali metal vapor mixing chamber 200 can also be interchangeably referred to as a “pre-saturation chamber” or “pre-sat chamber”.

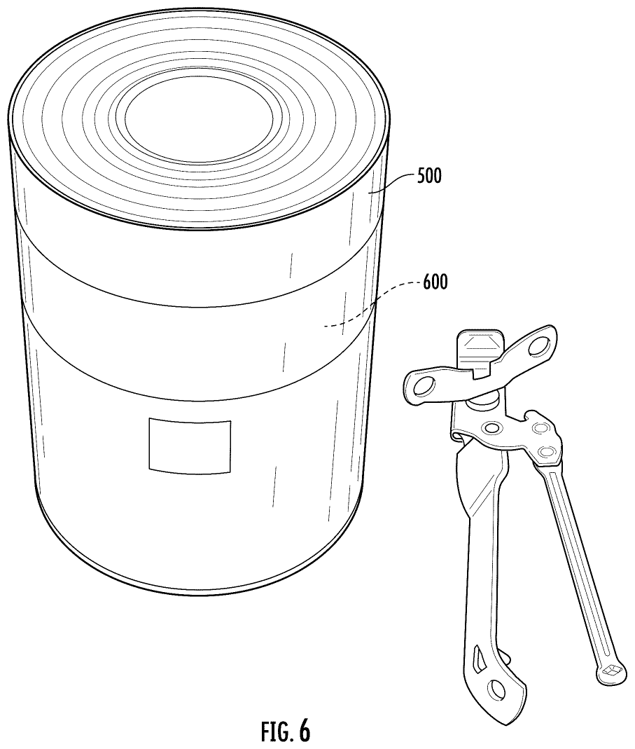

The load-lock chamber 210 generates alkali metal vapor, typically comprising or consisting essentially of only Rb vapor, for the optical pumping cell 22. The load-lock chamber 210 is configured to be loaded onsite with the alkali metal source 600 provided as a tablet or tablets in a solid form comprising the alkali metal and other chemicals such as a tablet comprising a blend of zirconium powder, rubidium molybdate and aluminum powder but may alternatively be provided in a powder form and may comprise other chemicals with the alkali metal. The load-lock chamber 210 is configured to be opened to load and reload the alkali metal source 600 into a container 215 in the load-lock chamber 210. The load-lock chamber 210 can (scalably) close with the alkali metal source 600 in the container 215 therein once loaded/reloaded with a desired amount of alkali metal source 600. The alkali metal source 600 can be shipped, sealed in a canister 500 (FIG. 6) separate from the optical pumping cell 22 or the pre-saturation chamber 200 or the lock-load chamber 210. Unlike conventional optical pumping cells 22, this configuration allows shipment of the optical pumping cell 22 “uncharged” making transport simpler and safer for the optical pumping cells 22 (no hazmat labeling, packaging, etc.).

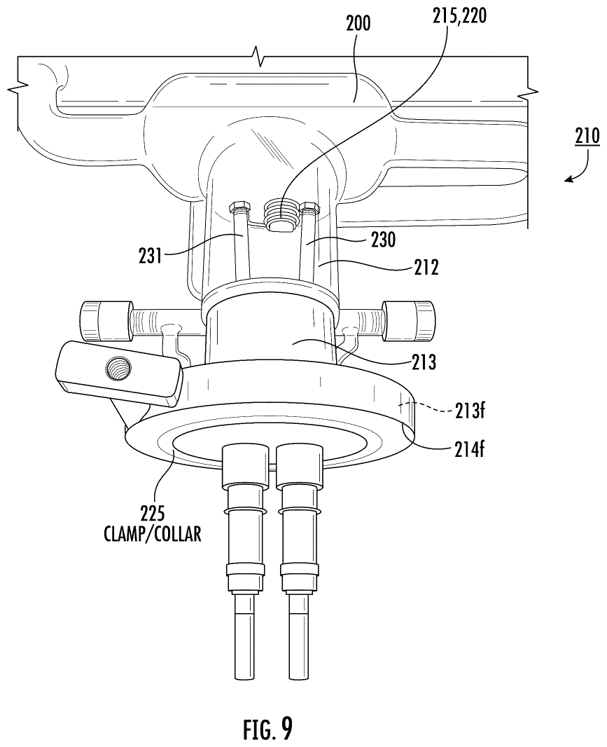

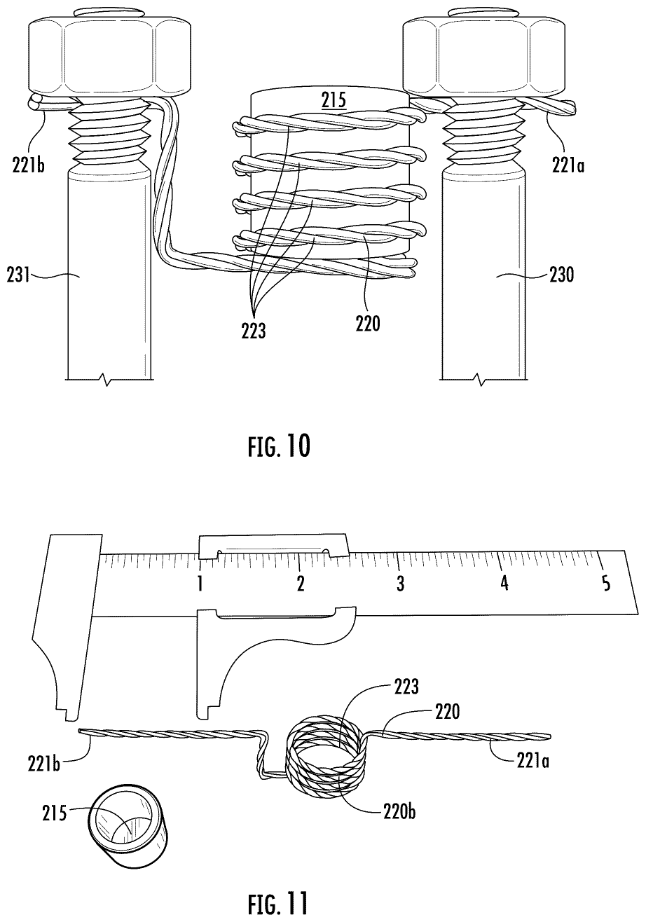

Referring to FIGS. 2-4, 7A-7C, and 8-11, example components of a load-lock chamber 210 is shown. A heater 220, shown optionally as a basket heater 220b, can at least partially surround the container 215 in the load-lock chamber 210 holding the alkali metal for vaporization/conversion from a solid form to a gas/vapor form/state. The heater 220 can be configured to support the container 215.

Where the heater 220 is provided as a basket heater 220b. the basket heater 220b can have twisted conductive semi-rigid malleable cable of one or more strands that can form a basket shape with a pair of free ends 221a, 221b (FIGS. 10, 11) extending outward from the basket shape and that couple to laterally spaced apart conductive posts 230, 231. The conductive posts 230, 231 can have free ends 230f, 231f, that are threaded 230t, 231t and that can couple to nuts 233 that to hold respective free ends 221a, 221b of the basket heater 220. The conductive posts 230, 231 can be electrically connected to at least one power connector 250 which is external to the load-lock chamber 210 through one or more pass throughs in the primary surface of the second member 214. The at least one power connector 250 can be coupled to a power source 275 to provide electrical current in a defined amperage to the basket heater 220 to provide a desired thermal/heat wattage output to the container 215 as is well known to those of skill in the art. The selected thermal/heat wattage is sufficient to vaporize alkali metal from the alkali metal source 600 in the container 215.

The load lock chamber 210 can have a first portion 212 that can be borosilicate glass and that merges into the vapor mixing chamber 200, which may also be borosilicate glass. The free ends 230f, 231f of the posts 230, 231 can reside inside the first portion 212 of the load lock chamber to position the basket heater 220 and the container 215 held therein in the first portion 212 of the load lock chamber 210.

The load lock chamber 210 can also have a first member 213 with a flange 213f that is integrally attached to the first portion 212 and that sealably, releasably couples to a second member 214 with a flange 214f. The first member 213 and the second member 214 can each be formed of one or more non-ferromagnetic metal. The first member 213 can be cylindrical and the second member can be configured as a disk. The first member 213 can be non-ferromagnetic metal and can transition from the flange to first portion as a glass-metal seal which may be formed by glassblowing alchemy. Glass types having progressively different coefficients of expansion can be built up to transition from metal to the borosilicate glass of the first portion 212 of the load lock-cell 210. An example glass-metal adaptor is part number SPO-250-450, pyrex borosilicate glass, 304 stainless steel, Accu-Glass, Inc., Valencia, CA, USA, recognizing different materials may be used.

In some embodiments, a locking collar 225 (which can also be referred to as a “clamp”) can hold the flanges 213f, 214f together in a closed, typically sealed, state and allow the first and second members 213, 214 to be decoupled to open the load-lock chamber 210 and allow access to the interior of the load lock chamber 210 and the container 215. However, other releasable assembly configurations may be used to provide the connection as will be known to those of skill in the art.

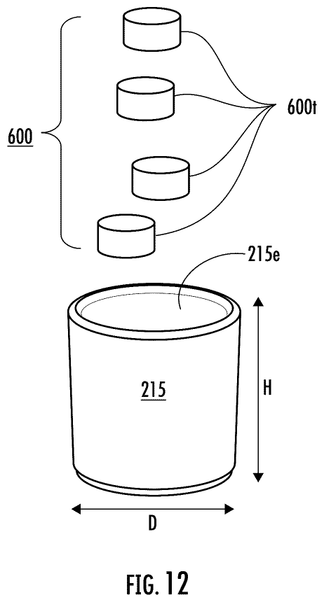

The posts 230, 231 can remain coupled to the second member 214 when opening the load-lock chamber 210. Moving the second member 214 away from the first member 213 can also move the free ends 230f, 231f of the posts 230, 231, in concert with the second member 214, away from the first portion 212 of the load lock chamber, typically out of the first member 213, providing access to the basket heater 220 and the container 215. The container 215 can be emptied of any remnants/ash and reloaded with new tablets 600t (FIG. 12). Alternatively, a new/unused container 215 with tablets 600t can be placed in the basket heater 220 after the used container is removed. Reattaching the second member 214 to the first member 213 positions the free ends 230f, 231f of the posts 230, 231 adjacent the vapor mixing chamber 200.

The first member 213 and/or the second member 214 can have an internal seal 217 such as an O-ring, gasket or other sealant material.

Referring to FIG. 3, for example, the container 215 and the basket heater 220 can be positioned to reside adjacent the vapor mixing chamber 200. The open end 215e of the container 215 can reside a distance “d” from a center of the vapor mixing chamber 200. The distance “d” can be in a range of 0.25-2 inches, in some embodiments. This allows the vaporized alkali metal Va to exit directly into a cross-flow of incoming noble gas mixture Gn and mix with the noble gas mixture before being flowably delivered, entrained in the noble gas mixture Gn in a sufficient amount for facilitating polarization of the noble gas, to the optical pumping cell 22. The manifold 10m and flow path through the vapor mixing chamber 200 are maintained at a positive pressure, closed to environmental conditions.

A heater 222 (FIG. 1) can heat the pre-sat chamber 200 in a range of 160-200 degrees C., typically about 185 degrees C., to heat the incoming pressurized noble gas mixture Gn prior to and/or during the mixing of the alkali metal vapor Va.

Referring to FIGS. 2 and 3, noble gas mixture Gn flows in through the inlet labeled Gin and from there flows through the Gas Preheater Zone 211 before entering the Vapor Mixing Chamber 200 where it mixes with the vaporized alkali metal Va before entering the cell 22 and subsequently exits though the Gas Outlet Gout. The valves 202 on the stems of the Gin/Gout allow the cell 22 to be closed off and removed from the system or simply sealed off from the rest of the system (sometimes desirable for finding/chasing leaks).

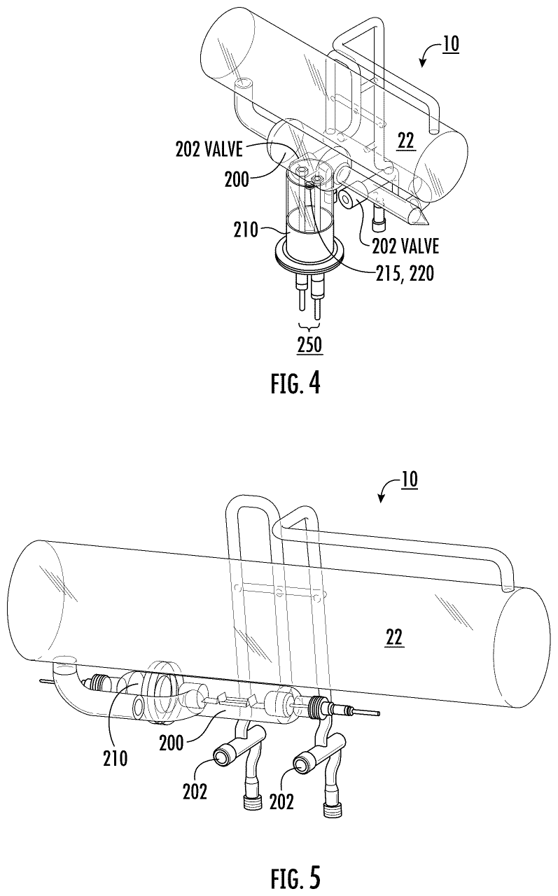

Referring to FIG. 5, it is shown that the load-lock chamber 210 can be oriented in a different manner from that shown in FIG. 4. As shown, the load-lock chamber 210 can be axially aligned with the vapor mixing chamber 200 instead of under the vapor mixing chamber 200 (FIG. 4).

Referring to FIGS. 6 and 12, the alkali metal source 600 for the container 215 of the load lock chamber 210 can be provided in solid form, such as in a powder or tablet form and shipped for use in a pressurized, hermetically sealed canister 500. FIG. 12 shows that the alkali metal source 600 can be provided by a plurality of tablets 600t that can be positioned in the container 215 at a first instance, then the load-lock chamber 210 can be closed and used over a plurality of production runs to produce a plurality of batches of hyperpolarized noble gas with vaporized alkali metal provided by heating the tablets 600t. The tablets 600t can have any shape or combinations of shapes. There can be any suitable number of tablets 600t, typically 3-6 tablets 600t, positioned in the container 215 at the first instance, shown as four in FIG. 12. In some embodiments, the tablets 600t can comprise Rb/Amax and may be obtained from SAES Group/SAES Advanced Technologies, S.p.A., 67051 Avezzano (AQ), Italy. These are tablets 600t that are a blend of Rubidium Molybdate (in a range of about 30%-40%), Zirconium powder (in a range of about 50%-60%, non pyrophoric)) and Aluminum powder (pyrophoric) (in a range of about 10%-12/5%).

While not wishing to be bound by any particular theory of chemical reaction, the rubidium vapor can be released via a redox reaction driven by the heating of the container 215 in the load-lock chamber 210. It is believed that no other undesired (detectable) constituent chemicals of the tablets 600t are vaporized into the noble gas mixture Gn in the mixing chamber 200. To the extent there may be chemicals other than the vaporized alkali metal provided to the noble gas mixture Gn from the alkali metal source, such is in trace amounts and/or are non-cytotoxic. It is also believed that besides its reducing action, the St 101 alloy is able to irreversibly sorb almost all the chemically active gases which are produced during the reduction reaction, thus preventing them from contaminating the alkali metal vapour.

Latex or other suitable protective gloves for tablet handling, masking and eye googles are to be used per the product Safety Data Sheet (RBSDS111621/1, Jul. 23, 2014) and Technical Specification (code 5F0421 dated Mar. 30, 2015).

In some embodiments, the tablets 600t can have a size in a range of 1-6 mm diameter and 1-3 mm thickness, but other sizes may be used. In some embodiments, each table can have Rb in a range of 10-40 mg, such as about 20-32 mg, and can be about 32 mg.

The tablets 600t can be placed into the container 215 side by side or stacked or partially stacked/overlaying one other

The optical pumping cell 22 and vapor mixing chamber 200 can be a monolithic unitary body. The first portion 212 of the load lock chamber 210 can also be integrated to the unitary body.

The load-lock chamber 210 is not required to be a vacuum load lock system. Typically, the load-lock chamber 210 is coupled to the fluid manifold 10m providing the pressurized noble gas mixture Gn by passing the vaporized alkali metal into a higher-pressure region. A regulated supply of UHP (ultra-high purity) nitrogen can be attached to the fluid manifold 10m. When the load-lock chamber 210 is opened, nitrogen flows out preventing room air from getting into the load-lock chamber 210 and other components of the polarizer. The flanges 213f, 214f can be scalably coupled back together with the nitrogen gas actively flowing. To be clear, no new gas path for the UHP nitrogen is required. Instead, the UHP nitrogen can be back-flowed through the condenser or, more typically, flow from the same connection as the noble gas mixture (xenon mix as we have it set up to cut over and flow UHP nitrogen (13, FIG. 1) through the noble gas mix feed line 10m, by closing the tank of noble gas (e.g., 129 xenon) mix 12. This insures positive pressure on the cells.

Referring to FIGS. 10 and 11, the basket heater 220 can have a stack of coiled segments 223 of the one or more strands of conductive cable forming the basket shape which can be sized and configured to snugly receive the container 215.

As shown in FIG. 12, the container 215 can have an outer diameter D in a range of 0.5 inches to 2 inches, such as about 1 inch, about 1.25 inches and about 1.5 inches, in some embodiments. The container 215 can have a constant outer diameter D or taper inward or outward over it′ height/length dimension H. The container 215 can have a length/height dimension H that is about the same or larger than the outer diameter D of the container 215. In some embodiments, the length/height dimension H is in a range of 1.1×-2× the outer diameter of the container 215. The container 215 and the basket heater 220 can be non-ferromagnetic. Although shown as a closed bucket/basket shaped container, more complex shapes may be used, such as a curvilinear shape over its height dimension or even a pyramid shape.

In some example embodiments, the container 215 can be formed of alumina and the basket heater 220 can be formed of tungsten.

Components of the load-lock chamber 210 can be obtained from KJ Lesker Company, Jefferson Part, PA, USA: Tungsten Basket: part #EVB8A3025W; Alumina Crucible: part #EVC1AO; Feedthrough: part number XTEMP-FT, XTEMP-HD, KP-200-K5-OAL4.15, KF50 base flange, (2) ¼ inch nickel conductors, slotted and threaded, 7.25 inches.

In some embodiments, the pre-saturation chamber 200 can be operated at higher temperature than the optical pumping cell 22. In some embodiments, the pre-saturation chamber 200 can be heated to about 185° C. and the basket heater 220 can be operated with a current in a range of about 20 A to 42 A. The optical pumping cell 22 can be used as in conventional polarizer systems with regards to flow rates and times.

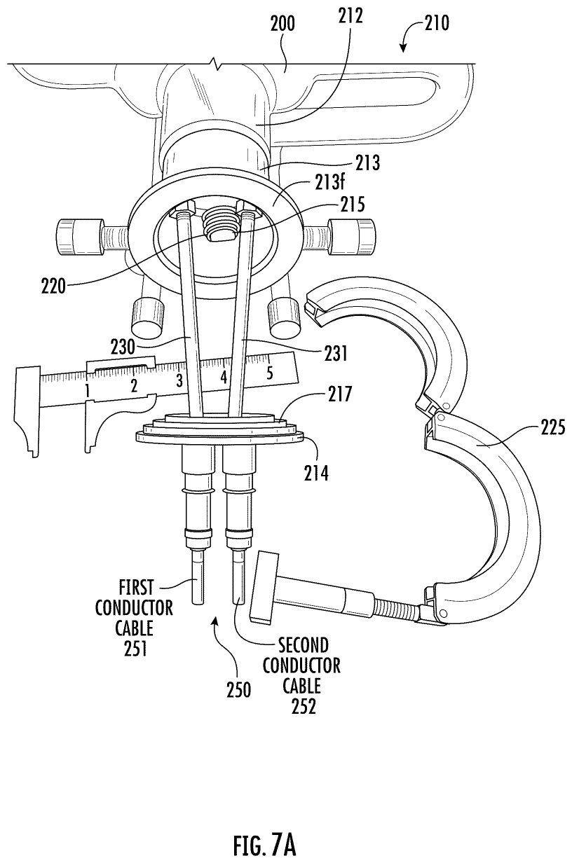

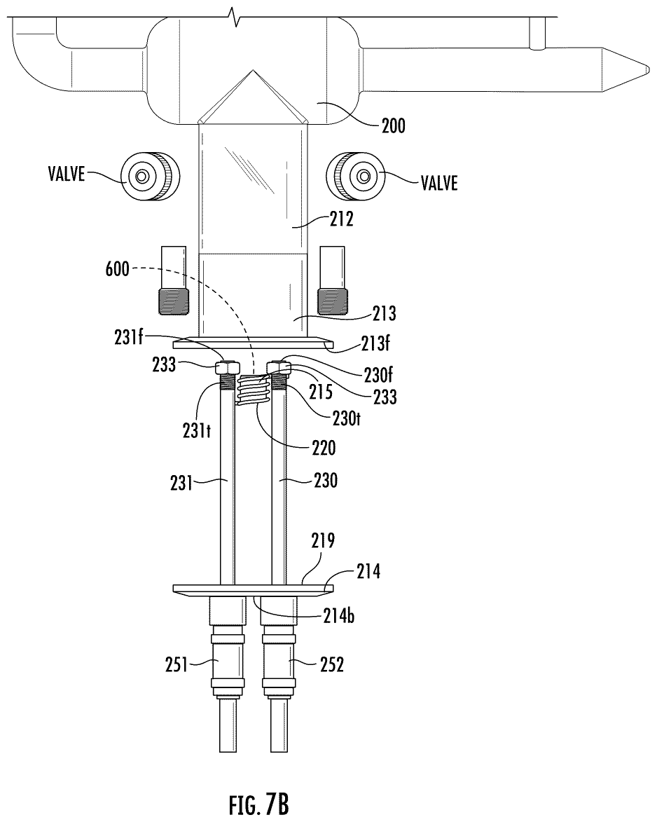

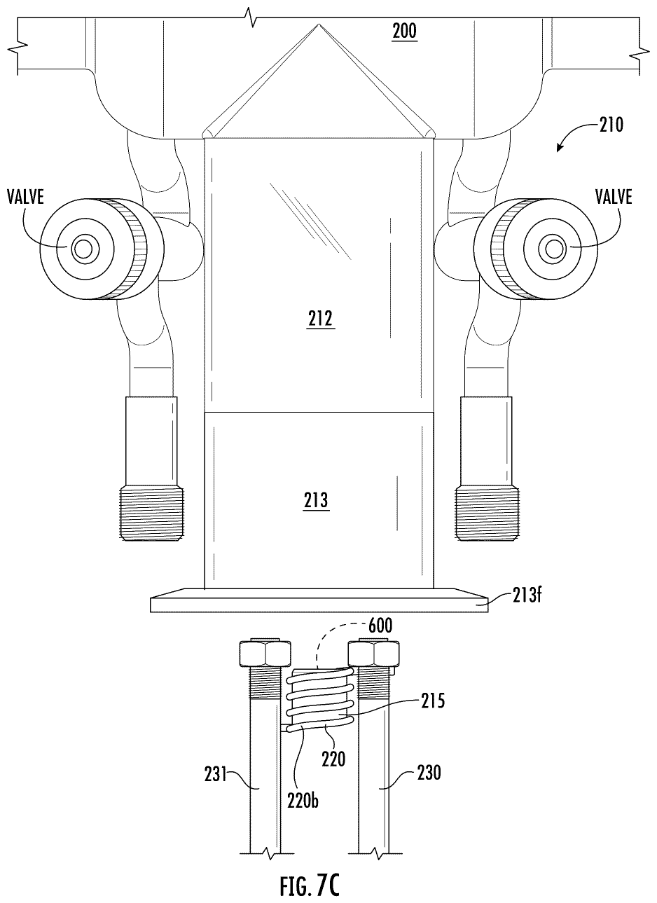

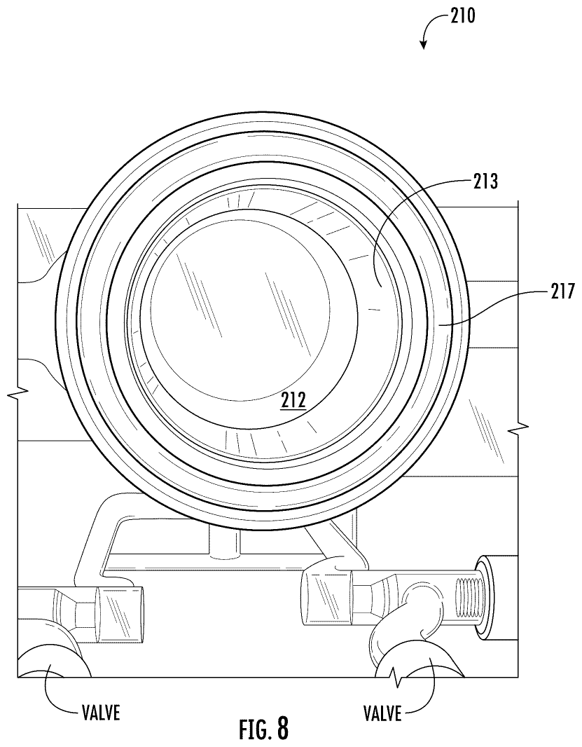

Testing of a prototype load-lock chamber 210, such as that shown in FIG. 7A with four tablets 600t as the source of the rubidium vapor (about 32 mg Rb each) was used to successfully polarize eighty-six (86) 300 mL batches and three (3) 1000 mL batches of hyperpolarized 129 Xenon with polarizations achieved that were no worse than the baseline for the conventional polarizer (˜40%).

The load-lock chamber 210 can be provided with materials devoid of ferromagnetic materials, e.g., non-ferromagnetic and non-depolarizing materials. For surfaces that may contact the alkali metal in solid and/or vapor/gas form, the surfaces can be heated to a sufficiently high temperature (e.g., 200° C.) for a sufficient time (e.g., 1 week) while under ultra-high vacuum to provide a suitably sterile device that is substantially free of impurities and can be at sufficient sterility for providing inhalable pharmaceutical grade products.

It is noted that, the present invention is not limited to any particular (hyper) polarizer configuration, embodiments of the invention are particularly suitable for high-volume, flow polarizer systems. These systems can take on various forms and use various components as is known to those of skill in the art. To be clear, different components and arrangements may be used and not all components shown are required.

Thus, referring again to FIG. 1, as is known by those of skill in the art, this figure illustrates an example of a modified compact flow-through high volume hyperpolarizer which is configured to (continually over a production run) produce and accumulate spin-polarized noble gases, i.e., the flow of gas through the unit is substantially continuous. As shown, the hyperpolarizer unit 10 includes a noble gas (¹²⁹Xe) supply 12 and a supply regulator 14. A purifier 16 can be positioned in the line to remove impurities such as water vapor from the system as will be discussed further below. The hyperpolarizer 10 can also include an ultra-high purity nitrogen source/canister 13, a flow meter 18 and an inlet valve 20 positioned upstream of the optical pumping cell (polarizer cell) 22, typically also upstream of the pre-saturation (“pre-sat”) chamber 200. An optic light source such as a laser 26 (either narrow or broad band, typically a diode laser array) is directed into the polarizer cell 22 through various focusing and light distributing means 24, such as lenses, mirrors, and the like. The light source is circularly polarized to optically pump the alkali metals in the cell 22. An additional valve 28 can be positioned downstream of the polarizer cell 22.

Next in line, is the cryo-collection system 30. The cryo-collection system 30 can be connected to the hyperpolarizer 10 by a pair of releasable mechanisms such as threaded members or quick disconnects 31, 32. This allows the cryo-collection system 30 to be easily detached, removed, or added, to and from the system 10.

The cryo-collection system 30 can be set to a gas mixture collection operating temperature using the cooler 340 and the gas mixture flows through the inlet/entry conduit 442 into the accumulator 42 and the nitrogen and helium vent out the outlet/exit conduit 442. During collection, valves 35, 37, and 58 are OPEN, and the flow control valve 57 is adjusted for the desired flow rate (FIG. 1). When a thaw of the collected ¹²⁹Xe is desired, the incoming valve 35 (FIG. 1) is closed along with valve 58, and valves 47, and 50b or 50c are opened, the controller 375 or a user electronically directs the heater 240 to activate (and optionally, the cooler to deactivate) whereby collected frozen ¹²⁹Xe is thawed and flowed out the outlet/exit conduit 444 to a container such as a collection vessel 155 such as a TEDLAR bag at the Xe outlet 50b for dispensing to a patient. In some embodiments, a pre-collection container 255 can be used to collect, measure and add N₂ from a medical grade (ultra-high purity) pressure N₂ source 152, such as a pressurized cylinder in communication with a regulator 153, to the thawed ¹²⁹Xe gas, then the measured amount can be dispensed to a single or multiple bolus collection container 155 such as a flexible bag which can be a TEDLAR bag for transportation to a use cite and dispensing to a patient. In this case, valve 50c is opened during the thaw.

A vacuum pump 60 is in fluid communication with the system 10 and may be in communication with a vacuum transducer 61. Additional valves to control flow and direct exit gas can be used and are shown at various points (shown as 52, 55). A shut-off valve 47 can be positioned adjacent, upstream of adjacent an “on-board” exit gas tap at valve 50b. Certain of the valves downstream of the cryo-collector 30 can be used for “on-board” thawing and delivery of the collected polarized gas. The system 10 can also include a digital pressure transducer 54 and a flow control device 57 along with a shut-off valve 58. The shut-off valve 58 can control the flow of gas through the entire system or unit 10 and can be used to turn the gas flow on and off. As will be understood by those of skill in the art, other flow control mechanisms, devices (analog and electronic) may be used within the scope of the present invention.

In operation, a gas mixture is introduced into the system at the gas source 12. As shown in FIG. 1, the gas source 12 is a pressurized gas tank which holds a pre-mixed gas mixture. The gas mixture includes a noble gas (the gas to be hyperpolarized) and buffer gas mixture. Preferably, for producing hyperpolarized ¹²⁹Xe, the pre-mixed gas mixture is about 90% He, about 5% or less ¹²⁹Xe (typically about 1% ¹²⁹Xe), and about 10% N₂. The gas mixture can be passed through the purifier 16 and introduced into the optical (polarizer) cell 22. The valves 20, 28 are on/off valves operably associated with the polarizer cell 22. The gas regulator 14 steps down the pressure from the gas tank source 12 (typically operating at 2000 psi or 136 atm) to about 1-10 atm for the system, e.g., about 1 atm, about 2 atm, about 3 atm, about 4 atm, about 5 atm, or between about 6-10 atm for the system. For systems with spectrally narrowed lasers, lower cell operating pressures of between about 1-3 atm may be particularly desirable.

Thus, during accumulation, the entire manifold (conduit, polarized cell, accumulator, etc.) can be pressurized to the cell pressure (e.g., about 3 atm). The flow in the unit 10 can be activated by opening valve 58 and is controlled by adjusting the flow control means 57. The typical residence time of the gas mixture in the optical cell 22 is about 10-30 seconds, i.e., it takes on the order of 10-30 seconds for the gas mixture to be hyperpolarized while moving through the cell 22.

For lightweight accumulators 42, the gas mixture is typically introduced into the cell 22 at a pressure of between about 1-3 atm and this pressure is about the same as that at the accumulator 42.

Of course, with hardware capable of operating at increased pressures, operating pressures of above 10 atm, such as about 20-30 atm can pressure broaden the Rb and absorb up to 100% of the optical light. In contrast, for laser linewidths less than conventional linewidths, lower pressures can be employed. The polarizer cell 22 can be a high-pressure optical pumping cell housed in a heated chamber with apertures configured to allow entry of the laser emitted light.

As noted above, various techniques have been employed to accumulate and capture polarized gases for use in MRI imaging of patients. For example, U.S. Pat. No. 5,642,625 to Cates et al., describes a high volume hyperpolarizer for spin polarized noble gas and U.S. Pat. Nos. 5,860,295; 5,809,801; 6,305.190; and 6,735,977 describe cryogenic accumulators for spin-polarized ¹²⁹Xe. These references are hereby incorporated by reference as if recited in full herein. As used herein, the terms “hyperpolarize” and “polarize” and the like, mean to artificially enhance the polarization of certain noble gas nuclei over the natural or equilibrium levels. Such an increase is desirable because it allows stronger imaging signals corresponding to better MRI images of the substance and a targeted area of the body. As is known by those of skill in the art, hyperpolarization can be induced by spin-exchange with an optically pumped alkali-metal vapor or alternatively by metastability exchange. See Albert et al., U.S. Pat. No. 5,545,396, which is incorporated by reference as if recited in full herein.

Turning again to FIG. 1, an example hyperpolarizer 10 is shown with at least once pre-saturation chamber 200. The chamber 200 can be relatively compact and can reside adjacent the entry port of the optical pumping cell 22. The polarizer 10 can include other components as is known by those of skill in the art (and are described below). The term “chamber” with respect to the pre-sat member and/or section of the gas flow path, refers to a region of a flow path that flowably supplies noble gas mixture into the optical pumping cell 22 with vaporized alkali metal from the load-lock chamber 210.

Optionally, the optical pumping cell 22 can include pairs of conduit legs 22a, 22b that extend to valves V, e.g., 20, 28 (which are typically KONTES valves).

The optical pumping cell 22 can be relatively compact with a volume capacity of between about 100 cc to about 500 cc, such as about 100 cc, about 200 cc, about 300 cc, about 400 cc and about 500 cc. The optical pumping cell 22 can also have larger sizes, such as between about 500 cc-1000 cc, for example.

As shown in FIG. 1, the hyperpolarizer 10 can comprise at least two different temperature-controlled zones T1, T2, one (T1) for the pre-saturation chamber 200 and at least one other (T2) for the optical pumping cell 22 so that T1>T2. The volume of the pre-saturation chamber V1 is also less than the volume V2 of the optical pumping cell 22.

In some embodiments, the pre-saturation chamber 200 in the T1 zone can be heated to temperatures between about 140 degrees C. and 300 degrees C., more typically between about 140 degrees Celsius to about 250 degrees Celsius, such as 140 degrees C., 150 degrees C., 160 degrees C., 170 degrees C., 180 degrees C., 185 degrees C., 190 degrees C., 200 degrees C., 210 degrees C., 220 degrees C., 230 degrees C., 240 degrees C. and 250 degrees C. The second temperature zone (T2) for the optical pumping cell 22 can be configured to have a temperature that is less than T1, typically with a temperature between about 70 degrees C. to about 200 degrees C., more typically between about 90 degrees C. to about 150 degrees C., such as about 95 degrees C., about 100 degrees C., about 110 degrees C., about 120 degrees C., about 140 degrees C. and about 150 degrees C., to maintain vapor pressure, in some embodiments. The zone T2 may also be configured to apply a temperature gradient of decreasing temperature from a greater temperature at a region proximate the inlet to a lower temperature proximate the exit, typically with a change that is about 10 degrees C., about 15 degrees C., about 20 degrees C., about 25 degrees C. or about 30 degrees C., for example.

The temperature zone T1 can comprise at least one (pre) heater 222 that can provide the desired heat to increase the temperature including conductive and/or convection heaters. The at least one heater 222 can be an electric heater. The at least one heater 222 can comprise one or more of an oven, infrared heaters, resistive heaters, ceramic heaters, heat lamps, heat guns, laser heaters, heat blankets (e.g., heat blanket that can be wrapped about the chamber 200 with at least one insulation layer, typically comprising Nomex®-fiberglass fibers, but other insulation materials may be used), pressurized hot fluid spray and the like. The at least one heater 222 can employ a plurality of different heater types. The at least one heater 222 can comprise an oven that encases or partially encases the chamber 200. The at least one heater 222 can comprise an internal heater in the chamber 200. The temperature zone T2 can also comprise at least one heater 122, typically comprising an oven. Each zone can be independently controlled to maintain a desired temperature or temperatures.

In some particular embodiments, in contrast to a normal optical pumping cell 22 maintained at between 160-180 degrees C., the optical pumping cell 22 can be held at a primary body temperature that is maintained at 150° C. or less, such as between 100° C. and 150° C., including, for example, about 100 degrees C., about 110 degrees C., about 120 degrees C., about 130 degrees C., about 140 degrees C., while Rb saturated vapor is picked up by the flowing gas stream in the pre-saturation chamber 200, which can be maintained at temperatures ranging from between about 150 to 250 degrees C., depending on the desired flow rates. In some particular embodiments, the pre-sat chamber 200 can be held at between 150 degrees C. to about 185 degrees C.

In some embodiments, the hyperpolarizer 10 employs the optical pumping cell 22 at a pressure of about 3 atm. It is contemplated that a spectrally narrowed laser, that has been detuned by about 0.25-0.50 nm from the alkali D1 resonance at that pressure. As will be understood by one of skill in the art, a small pressure shift in resonance occurs from vacuum to the 3 atm pressure which can depend on the buffer gas composition. For example, in vacuum, Rb D1 resonance is at 794.8 nm, whereas at 3 atm with the same buffer gas mixture, it is shifted to a slightly lower wavelength of 794.96 nm.

The hyperpolarizer 10 can employ helium buffer gas to pressure broaden the Rb vapor absorption bandwidth. The selection of a buffer gas can be important because the buffer gas—while broadening the absorption bandwidth—can also undesirably impact the alkali metal-noble gas spin-exchange by potentially introducing an angular momentum loss of the alkali metal to the buffer gas rather than to the noble gas as desired.

Hyperpolarized gas, together with the buffer gas mixture, exits the optical (pumping/polarizer) cell 22 and travels along the manifold (e.g., conduit), then enters the cryo-collection system 30. The gas mixture is directed into the accumulator 42 and along a gas mixture flow path 141p. As discussed above, in operation, the hyperpolarized ¹²⁹Xe gas is exposed to temperatures below its freezing point and collected as a frozen product in the accumulator 42. The remainder of the gas mixture remains gaseous and exits the accumulator 42 through outlet/exit conduit 444 (FIG. 2). The hyperpolarized gas is collected in the accumulator 42 (as well as stored, transported, and preferably thawed) in the presence of a magnetic field, generally on the order of at least 500 Gauss, and typically about 2 kiloGauss, although higher fields can be used. Lower fields can potentially undesirably increase the relaxation rate or decrease the relaxation time of the polarized gas. The magnetic field can be provided by permanent magnets positioned about a magnetic yoke. Once a desired amount of hyperpolarized gas has been collected in the accumulator 42, valve 35 can be closed. The manifold of the hyperpolarizer 10 downstream of the valve 28 can be allowed to depressurize to about 1.5 atm before the flow valve 58 is closed. After closing the flow valve 58, valves 52 and 55 can be opened to evacuate the remaining gas in the manifold. Once the outlet plumbing is evacuated, valve 59 is closed A receptacle/container such as a bag or other vessel can be attached to the outlet 50. Valves 47, 50b, 52, and 55 can be opened to evacuate the attached bag 155.

Alternatively, in some embodiments like FIG. 1, the manifold can be configured to pull a vacuum on the bag (or vessel into which to ¹²⁹Xe is to be expanded) during the entire collection time. In this case, valve 59 is closed during flow, and valves 47, 50b, 52, and 55 are open. In this configuration, the valves 52 and 55 are closed during the thaw so that thawed ¹²⁹Xe gas is not lost to the vacuum pump.

If the valve 52 is not closed, then valve 55 is preferably closed to prevent the evacuation of polarized thawed gases. The flow channels on the downstream side of the cell 22 can be formed from materials which minimize the decaying effect on the polarized state of the gas. Coatings can also be used such as those described in U.S. Pat. No. 5,612,103, the disclosure of which is hereby incorporated by reference as if recited in full herein. In the “on-board” thaw operation, valve(s) 37 in the exit flow path is opened to let the gas out. It then proceeds through valve 47 to outlet 50.

Examples of suitable isolation valves 35, 37 include Swagelok valves or KIMBLE KONTES valves.

In some embodiments, the isolation valves 35, 37 are in communication with the primary flow channel and the (buffer gas) exit/outlet channel 444, respectively, and each can adjust the amount of flow therethrough as well as close the respective paths to isolate the accumulator from the system 10 and the environment.

The flowcharts and block diagrams of certain of the figures herein illustrate exemplary architecture, functionality, and operation of possible implementations of embodiments of the present invention. It should also be noted that in some alternative implementations, the functions noted in the blocks may occur out of the order noted in the figures. For example, two blocks shown in succession may in fact be executed substantially concurrently or the blocks may sometimes be executed in the reverse order or two or more blocks may be combined, depending upon the functionality involved.

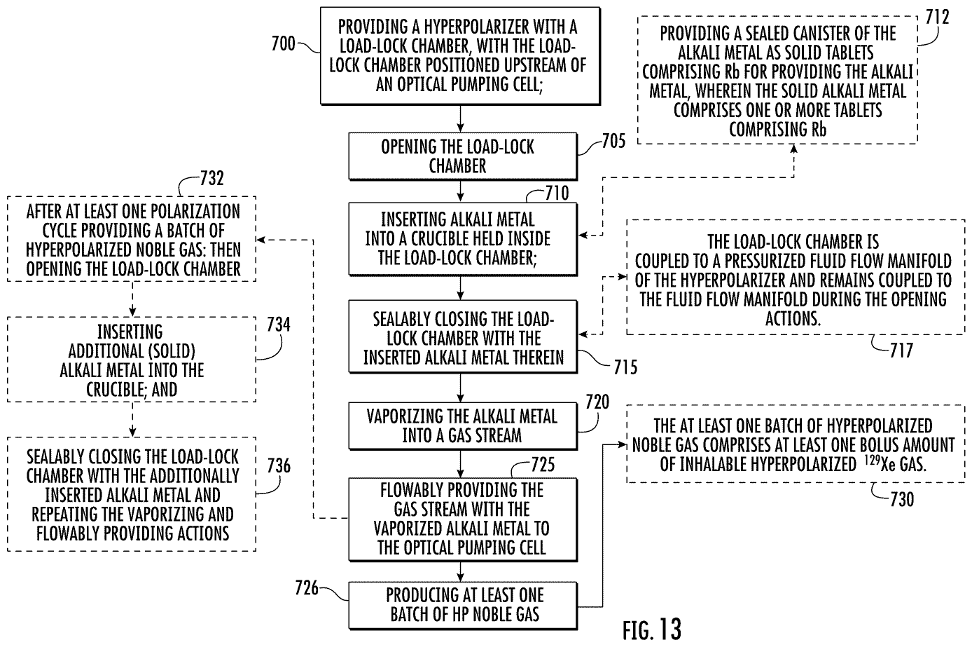

FIG. 13 is a flow chart of example actions that can be used to provide alkali metal to a noble gas mixture for an optical pumping cell for producing hyperpolarized noble gas. As shown, a hyperpolarizer with a load-lock chamber is provided, with the load-lock chamber positioned upstream of an optical pumping cell (block 700). The load-lock chamber can be opened (block 705). A solid alkali metal source can be inserted into a container held inside the load-lock chamber (block 710). The load-lock chamber with the inserted alkali metal source can be sealably closed (block 715). Then alkali metal from the alkali metal source can be vaporized and flowed into a noble gas mixture stream (block 720). The noble gas mixture stream with the vaporized alkali metal can be flowably provided to the optical pumping cell (block 725). At least one batch of hyperpolarized noble gas is produced (block 726).

One batch can provide at least one bolus amount of inhalable ¹²⁹Xe gas (block 730).

The actions/method can also include, after producing at least one batch of HP noble gas, opening the load-lock chamber (block 726) then inserting additional a solid alkali metal source (e.g., additional table into the container (734); and (sealably) closing the load-lock chamber with the additionally inserted solid alkali metal source and repeating the vaporizing, flowably providing and producing actions (736).

The method can further include providing a sealed canister of the alkali metal source with the alkali metal source configured as a plurality or tablets comprising Rb (block 712).

The load-lock chamber can be coupled to a pressurized fluid flow manifold of the hyperpolarizer and can remain coupled to the fluid flow manifold during the opening actions with ultra-high purity nitrogen directed to flow from the pressurized fluid flow manifold and out of the opened load-lock chamber (block 717).

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clause are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

That which is claimed is:

1. A hyperpolarizer comprising:
a spin exchange optical pumping cell; and
a load-lock chamber positioned upstream of and in fluid communication with the spin exchange optical pumping cell, wherein the load-lock chamber is configured to hold an alkali metal source therein for vaporization of alkali metal from the alkali metal source into a gas stream provided to the spin exchange optical pumping cell.

2. The hyperpolarizer of claim 1, wherein the load-lock chamber is configured to have an open position and a sealably closed position, and wherein, when in the sealably closed position, the alkali metal is vaporized into the gas stream.

3. The hyperpolarizer of claim 1, further comprising:
a container holding the alkali metal source in a solid state in the load-lock chamber; and
a basket heater in the load-lock chamber at least partially surrounding the container.

4. The hyperpolarizer of claim 1, wherein a body of the load-lock chamber, the container and the basket heater are all formed of non-ferromagnetic materials.

5. The hyperpolarizer of claim 1, wherein the load-lock chamber has a first end portion that is in fluid communication with and that merges into an alkali metal vapor mixing chamber, both of which reside upstream of the spin exchange optical pumping cell.

6. The hyperpolarizer of claim 5, wherein the load-lock chamber has a second end portion that comprises a first member that is sealably and releasably coupled to a second member, and wherein the second member has a closed primary surface and comprises at least one electrical feed through extending through the closed primary surface configured to couple to a power source.

7. The hyperpolarizer of claim 6, wherein the first end portion comprises borosilicate glass, wherein the first member comprises a non-ferromagnetic cylinder with a flange sealed to the borosilicate glass, and wherein the second member comprises a non-ferromagnetic disk with a flange that faces and abuts the flange of the first member when the load-lock chamber is in a closed position.

8. The hyperpolarizer of claim 6, further comprising a first conductive post and a second conductive post extending in the load-lock chamber, each of which terminates adjacent the vapor mixing chamber, wherein the basket heater is attached to the first conductive post and the second conductive post.

9. The hyperpolarizer of claim 3, further comprising an alkali metal source held by the container, wherein the alkali metal source is in a solid state.

10. The hyperpolarizer of claim 9, wherein the alkali metal source comprises at least one of Rb, Cs, Na, and K.

11. The hyperpolarizer of claim 1, further comprising an alkali metal source comprising Rubidium.

12. The hyperpolarizer of claim 11, wherein the alkali metal source comprises a plurality of tablets of Rb/Amax.

13. The hyperpolarizer of claim 1, further comprising a sealed canister comprising the alkali metal source, wherein the sealed canister is configured to be opened at a use site to provide the alkali metal source for the load-lock chamber.

14. The hyperpolarizer of claim 1, further comprising a pressurized gas manifold in fluid communication with the load-lock chamber and a supply of ultra-high purity nitrogen coupled to the pressurized gas manifold, wherein the hyperpolarizer is configured to direct ultra-high purity nitrogen to flow through the pressurized gas manifold and out the load-lock chamber when the load-lock chamber is in an open state for reloading alkali metal source into the load-lock chamber to thereby inhibit impurities from entering the load-lock chamber.

15. A flow-through spin exchange optical pumping (SEOP) hyperpolarized gas production system for producing hyperpolarized gas comprising:
a pressurized noble gas mixture in a gas manifold;
a load-lock chamber in fluid communication with the gas manifold with the pressurized noble gas mixture and configured to provide vaporized alkali metal to the pressurized noble gas mixture; and
a flow-through optical pumping cell in fluid communication with the gas manifold with the pressurized gas mixture and positioned downstream of the load-lock chamber, wherein the flow-through optical pumping cell is configured to provide hyperpolarized noble gas.

16. The flow-through SEOP gas production system of claim 15, wherein the hyperpolarized noble gas is hyperpolarized ¹²⁹Xe gas.

17. The flow-through SEOP gas production system of claim 15, further comprising an alkali metal mixing chamber in fluid communication with the load-lock chamber and positioned upstream of the flow-through optical pumping cell, wherein a magnetic field B₀ surrounds at least part of the flow-through optical pumping cell, and wherein the load-lock chamber is positioned in or adjacent the magnetic field and comprises only non-ferromagnetic materials.

18. A method of providing alkali metal for a hyperpolarizer, comprising:
providing a hyperpolarizer with a load-lock chamber, with the load-lock chamber positioned upstream of an optical pumping cell;
opening the load-lock chamber;
inserting a solid alkali metal source into a container held inside the load-lock chamber;
sealably closing the load-lock chamber with the inserted alkali metal source; then vaporizing alkali metal from the alkali metal source into a noble gas mixture stream;
flowably providing the noble gas mixture stream with the vaporized alkali metal to the optical pumping cell; and
producing at least one batch of hyperpolarized noble gas.

19. The method of claim 18, further comprising:
opening the load-lock chamber; then
inserting an additional solid alkali metal source into the container; and
sealably closing the load-lock chamber with the additionally inserted solid alkali metal source and repeating the vaporizing, flowably providing and producing actions.

20. The method of claim 18, further comprising providing a sealed canister of the alkali metal source with the alkali metal source configured as a plurality or tablets comprising Rb.

21. The method of claim 18, wherein the load-lock chamber is coupled to a pressurized fluid flow manifold of the hyperpolarizer and remains coupled to the fluid flow manifold during the opening actions with ultra-high purity nitrogen directed to flow from the pressurized fluid flow manifold and out of the opened load-lock chamber.

22. The method of claim 18, wherein the at least one batch of hyperpolarized noble gas comprises at least one bolus amount of inhalable hyperpolarized ¹²⁹Xe gas.
